(19) United States
(12) Patent Application Publication
(10) Pub. No.: US 2006/0290366 A1
(43) Pub. Date: Dec. 28, 2006

(54) Monitoring multiple electronic devices under test

(75) Inventors: Hon Lee Kon, Penang (MY); Daniel J. Dangelo, Phoenix, AZ (US)

Correspondence Address: SCHWABE, WILLIAMSON & WYATT, PACWEST CENTER, SUITE 1900, 1211 S.W. FIFTH AVE., PORTLAND, OR, 97204, US

(73) Assignee: Intel Corporation

(21) Appl. No.: 11/169,598

(22) Filed: Jun. 28, 2005

(51) Int. Cl. G01R 31/02

(52) U.S. Cl. 324/760

(57) ABSTRACT

An apparatus and method for monitoring temperatures of multiple electronic devices under test are described herein.

### TECHNICAL FIELD

Embodiments of the invention relate generally to the field of electronic device manufacturing, and more particularly to monitoring of electronic devices during thermal testing of the electronic devices.

### BACKGROUND

Burn-in process or test involves subjecting chips or dice to relatively extreme conditions such as high and low temperatures in order to cause failures in dice that would pass a normal test but fail in early use by users of the dice. During the test, lots or batches of dice are typically tested together by placing the dice onto a test board such as a Burn-in Board (BIB). The test board is similar to a motherboard except with multiple sockets that the dice may be placed into, each socket holding one die. For testing of extreme temperature conditions, tight temperature control is generally required for accurate testing.

During a burn-in test for extreme temperature conditions, heat is generated by the dice themselves by supplying power to the dice. The power that is supplied to the dice may also be used to accelerate the failure of defective devices. Typically the power that is supplied is above the power that would be normally supplied to the dice under normal operating conditions. A coolant solution may be applied to all dice under test to reduce the temperature of the dice being tested.

### BRIEF DESCRIPTION OF THE DRAWINGS

Embodiments of the invention are illustrated by way of example and not by way of limitation in the figures of the accompanying drawings, in which like references indicate similar elements and in which:

FIG. 1 is a block diagram of a system for monitoring multiple electronic devices and for controlling the thermal conditions of the multiple electronic devices in accordance with some embodiments of the invention;

FIG. 2 illustrates a sensor selection circuitry of FIG. 1, in further detail, in accordance with some embodiments;

FIG. 3 illustrates an analog switch bank of FIG. 2 coupled to multiple temperature sensors in accordance with some embodiments; and

FIG. 4 illustrates an example temperature sensor that may be employed in the system illustrated in FIG. 1, in accordance with some embodiments.

### DETAILED DESCRIPTION OF ILLUSTRATIVE EMBODIMENTS

Illustrative embodiments of the present invention include an apparatus for monitoring multiple electronic devices under test. The electronic devices may be embodied in the form of a plurality of dice and the test being performed may be a burn-in process that exposes the plurality of dice to relatively extreme temperature conditions. The monitoring of the electronic devices may be the monitoring of the temperatures of the electronic devices.

Various aspects of the illustrative embodiments will be described using terms commonly employed by those skilled in the art to convey the substance of their work to others skilled in the art. However, it will be apparent to those skilled in the art that alternate embodiments may be practiced with only some of the described aspects. For purposes of explanation, specific materials and configurations are set forth in order to provide a thorough understanding of the illustrative embodiments. However, it will be apparent to one skilled in the art that alternate embodiments may be practiced without the specific details. In other instances, well-known features are omitted or simplified in order not to obscure the illustrative embodiments.

Further, various operations will be described as multiple discrete operations, in turn, in a manner that is most helpful in understanding the present invention; however, the order of description should not be construed as to imply that these operations are necessarily order dependent. In particular, these operations need not be performed in the order of presentation.

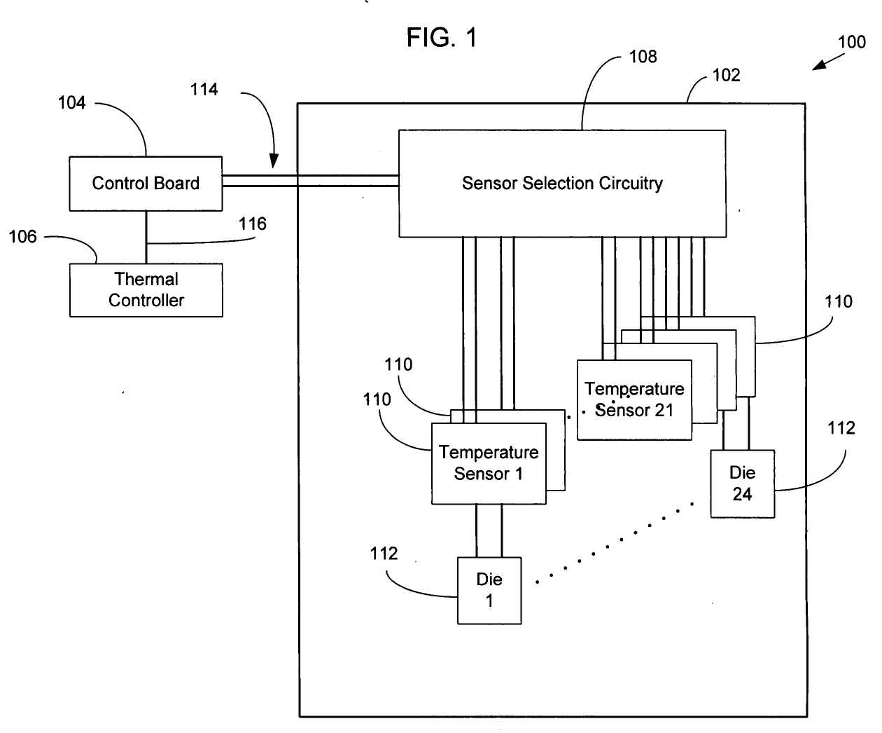

FIG. 1 depicts a block diagram of a system including a test board that can monitor the temperatures of multiple electronic devices during a test process of the electronic devices in accordance with some embodiments. The electronic devices may be, for example, central processing units (CPUs), volatile memory devices, chipsets, and/or any other type of electronic devices that may be embodied in the form of dice. For the embodiments, the system 100 may include a test board 102, a control board 104 and a thermal controller 106. Multiple dice 112 may be placed onto the test board 102 coupling the multiple dice 112 to multiple temperature sensors 110, each of the dice 112 being coupled to corresponding temperature sensors 110 that may be embedded in the test board 102. The test board 102, in some cases, may be a burn-in board (BIB) that may be employed in a burn-in process.

The test board 102 may be a substrate similar to a motherboard but with multiple sockets for receiving multiple dice, each of the sockets receiving a single die 112. In various embodiments, 18 or more sockets may be present on the surface of the test board 102 to receive 18 or more dice 112. In some embodiments, at least 24 sockets may be present on the test board 102 to receive 24 dice 112. The dice 112 that may be placed into the sockets may each include one or more thermal diodes that are each coupled to two pins, each pin being coupled to the opposite ends of a thermal diode. When a die 112 is placed into one of the sockets, the thermal diode pins are coupled to a temperature sensor 110 that may be embedded in the test board 102 via conductive leads that are coupled to the temperature sensor 110. In order to measure the temperature of a die, the temperature sensor steers bias current through the conductors to the thermal diode, measuring the forward biased voltage and computing the temperature.

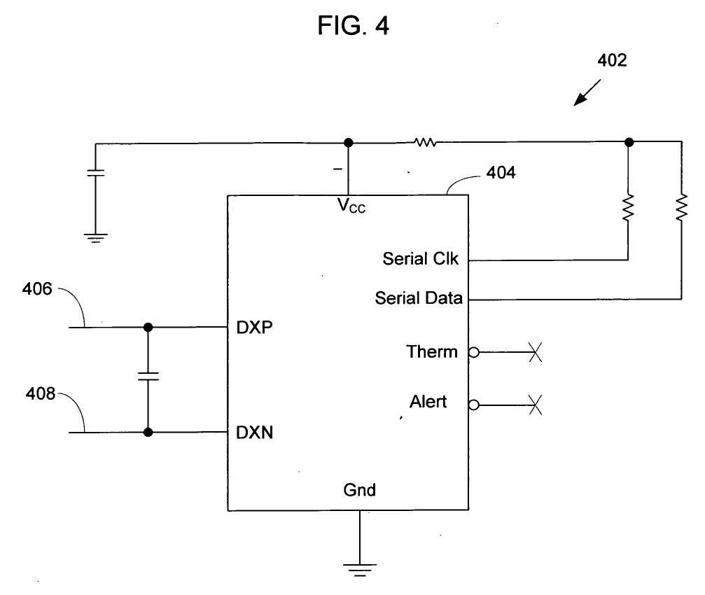

In some embodiments, one or more of the temperature sensors 110 may be of the type that can measure both remote and local temperatures (see, for example, FIG. 4), the remote temperature being the temperature of the die 112 that a temperature sensor 110 is coupled to and the local temperature being the temperature of the temperature sensor 110 itself (i.e., the temperature of the test board location where the temperature sensor is located). As previously described, one or more thermal diodes may be embedded in each of the dice 112 and both remote and local temperatures may be measured by the corresponding temperature sensors 110. In certain embodiments, the temperature sensors 110 may of the type that continuously take temperature measurements and may only output the latest temperature measurements when prompted to do so. Each of the temperature sensors 110 may be assigned a unique sensor identifier or device code address. The sensor identifiers may facilitate the prompting of specific temperature sensors to provide temperature measurements, one temperature sensor at a time thus avoiding data contention when, for example, a single serial bus architecture is employed.

The test board 102 may further include a sensor selection circuitry 108 that is coupled to the temperature sensors 110. Note that although the sensor selection circuitry 108 is depicted as being part of the test board 102 in FIG. 1, in other embodiments, the sensor selection circuitry 108 may be external to the test board 102. In accordance with various embodiments, the sensor selection circuitry 108 may be employed to selectively control the temperature sensors 110 based on input provided by, for example, the control board 104. The selective control of the temperature sensors 110 may include prompting the temperature sensors 110 to output the temperature measurements (i.e., measured temperatures) of the multiple dice 112 that the temperature sensors 110 may be coupled to. In various embodiments, the temperature measurements of the multiple dice 112 may be outputted by the sensor selection circuitry 108 serially.

The sensor selection circuitry 108 may receive input from an external source such as, for example, the control board 104. The input received may be used to control the output of temperature readings taken by the temperature sensors 110. In various embodiments, the sensor selection circuitry 108 may output the measured temperatures to the control board 104 at a sampling speed of 4 Hz or greater (i.e., if there are 24 dice being tested, 24 temperature measurements are generated four times or more per second). In some embodiments, the sensor selection circuitry 108 may output the measured temperatures at a sampling speed of at least 8 Hz or more.

The control board 104 may be used to control and to receive data (e.g., measured temperatures of the dice 112) from the test board 102. The control board 104, among other things, may further provide voltage to the test board 102 to provide power to the electronic devices (i.e., dice 112) being tested. In some embodiments, the control board 104 may be a power delivery board (PDB). The power delivered to the test board 102 may be used to power the test board 102 as well as the dice 112 that may be on the test board 102.

The control board 104, in various embodiments, may be coupled to the sensor selection circuitry 108 via a serial bus 114. For these embodiments, the control board 104 may transmit a signal to the sensor selection circuitry 108 via the serial bus 114 that may prompt the temperature sensors 110 to output temperature measurements of their corresponding dice 112. Such a signal may contain sensor identifier (e.g., device address code) and temperature read command pairs. Each of these pairs may be used to prompt specific temperature sensors 110 to output temperature measurements in a, for example, serial or sequential manner. The measured temperatures may then be transmitted serially to the control board 104 via the serial bus 114.

The serial bus 114 may include at least one input/output (I/O) serial bus that may be made of two conductive lines or wires. One line may be employed as a data line while the other line may function as a clock line.

A thermal controller 106 may be electronically coupled to the control board 104 via, for example, another serial bus 116. The thermal controller 106 may be controlled by the control board 104 and may be used to thermally control the thermal conditions of the dice 112 under test. In particular, the control board 104 may provide the measured temperatures received from the test board 102 and route the measured temperature data to the thermal controller 106, which takes the measured temperatures and based on the measured temperatures, may control the introduction of coolant solution to the devices under test (e.g., dice 112).

Operationally, the system 100 may monitor and control the temperatures of the plurality of dice 112 when the control board 104 initially transmits a signal containing sensor identifier and temperature read command pairs to the test board 102 via the serial bus 114. The sensor identifier and temperature read command pairs are then processed by the sensor selection circuitry 108 and based on the sensor identifier and temperature read command pairs contained in the signal, may prompt the temperature sensors 110 to output temperature measurements of their corresponding dice 112. In various embodiments, the temperature measurements may be outputted serially so that no two temperature sensors may output temperature measurements at the same time.

As a result, the outputted measured temperatures from the temperature sensors 110 may be outputted serially and the measured temperatures serially sent back to the control board 104 via the serial bus 114. The control board 104 may then take the measured temperatures received from the temperature sensors and use them to control the thermal conditions of the dice 112 under test using, for example, at least the thermal controller 106. The thermal conditions of the dice 112 may also be controlled by selectively controlling the power delivered to the dice by the control board 104.

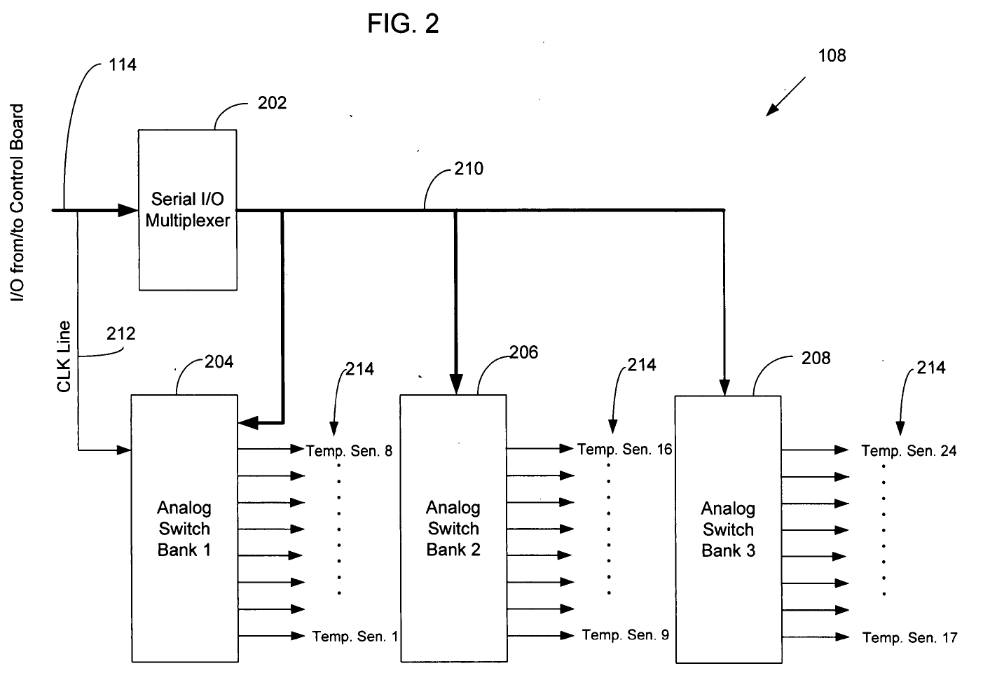

FIG. 2 depicts the sensor selection circuitry 108 of FIG. 1, in further detail, in accordance with some embodiments. For the embodiments, the sensor selection circuitry 108 may include a serial input/output (I/O) multiplexer 202 and multiple analog switch banks 204 to 208, each of the analog switch banks 204 to 208 include multiple analog switches. The three analog switch banks 204 to 208 are each coupled to different groups of temperature sensors 214 (Temperature Sensor 1 to Temperature Sensor 8 for analog switch bank 204, Temperature Sensor 9 to Temperature Sensor 16 for analog switch bank 206, and Temperature Sensor 17 to Temperature Sensor 24 for analog switch bank 208). In this illustration, each temperature sensor group is made up of eight temperature sensors that may each monitor eight different electronic devices (i.e., dice). Note that in other embodiments, the number of analog switch banks and the number of temperature sensors that each of the analog switch banks are coupled to may vary from that which is depicted in FIG. 2.

The serial I/O multiplexer 202, in various embodiments, may be coupled to the serial bus 114 of FIG. 1. The serial bus 114 may include two lines, a data line for transmitting input/output to and from the serial I/O multiplexer 202 and the temperatures sensors 214, and a clock line. Note that although not depicted in FIG. 2 both the serial I/O multiplexer 202 and the temperature sensors 214 may be coupled to a common data line of the same serial bus (i.e., serial bus 114). In various embodiments, the serial I/O multiplexer 202 may be employed to select the appropriate analog switch banks 264 to 208 to allow the temperature read commands to reach the intended temperature sensors in a serial manner via a data line 210. The selection of the appropriate analog switch banks 202 to 208 may be based at least upon the sensor identifiers of the sensor identifier and read command pairs. In some embodiments, the outputted temperature measurements may be outputted sequentially or serially from the temperature sensors 214. The outputted temperature measurements from the selected temperature sensors may be received serially by the control board 104 through the serial bus 114.

Functionally, the serial I/O multiplexer 202 may “read” a sensor identifier (e.g., device address code) that is received through the data line of the serial bus 114 and based on the sensor identifier, determine which of the analog switch banks 204 to 208 should be selected in order to prompt a specific temperature sensor to output a temperature reading. The selected analog switch bank 204 to 208 may then be configured via the data line 210 to prompt a specific temperature sensor that it is coupled to to output at least a temperature reading (i.e., measured temperature) of its corresponding electronic device (i.e., device under test—DUT). This may be accomplished by matching the sensor identifier of the sensor identifier and temperature read command pair to the appropriate temperature sensor having the same sensor identifier assigned to it.

The actual prompting of a temperature sensor may be as a result of the analog switch bank that the temperature sensor is associated with coupling the temperature sensor to a clock line 212 that is coupled to the clock line of the serial bus 114. Note that although in FIG. 2 only analog switch bank 204 is shown to be coupled to a clock line 212, in actuality, each of the other two analog switch banks 206 and 208 may also be each coupled to the same clock line that are coupled to the clock line of the serial bus 114. The coupling of each of the analog switch banks 204 to 208 to a common clock line (e.g., clock line 114) may assure that no two temperature readings or measured temperatures from different temperature sensors are outputted at the same time which could result in data contention in a system employing serial bus architecture.

As previously described, both the serial I/O multiplexer 202 and the temperature sensors 214 may be coupled to a common data line. In order to prompt a specific temperature sensor to output a temperature reading, the temperature sensor will be clocked (via coupling to the clock line 212) to receive the temperature read command that is associated with the sensor identifier that was initially read by the serial I/O multiplexer 202. The temperature read command along with the coupling of the temperature sensor to the clock line 212 will prompt the temperature sensor to output a temperature measurement. The temperature sensor may be continuously reading the temperature of its corresponding device but may only output the latest temperature measurement. Note that because the serial I/O multiplexer 202 and the temperature sensors 214 are all coupled to the same data line, the serial I/O multiplexer 202 will also see the temperature read command. However, the serial I/O multiplexer 202 will ignore the temperature read command since the device address that may be embedded in the temperature read command will not be the device address for the serial I/O multiplexer 202. The other temperature sensors may also see the temperature read command but will also not process the read command because they are not coupled to the clock line 212. The temperature measurement produced by the temperature sensor may be outputted back to the same data line used to receive the temperature read command.

The above identified sensor selection circuitry components may operate together in order to output multiple temperature measurements from multiple temperature sensors that are coupled to multiple devices (e.g., dice 112). In order to appreciate how these components may operate together to output a single temperature reading from a single temperature sensor, such as temperature sensor 1, the following example is provided. Initially, a sensor identifier and temperature read command pair meant to prompt temperature sensor 1 (Temp. Sen. 1) to output a temperature reading is received by the sensor selection circuitry 108 via the serial bus 114. The serial I/O multiplexer 202 may read the sensor identifier and select and set or configure analog switch bank 204 so that temperature sensor 1 may be clocked or coupled to the clock line 212.

Next, temperature sensor 1 as a result of being coupled to the clock line 212 will be prompted to read the temperature read command associated with the sensor identifier. Note again that although the serial I/O multiplexer 202 and the other temperature sensors are also coupled to the same data line as temperature sensor 1, only temperature sensor 1 will read or process the temperature read command. This is because, again, in the case of the serial I/O multiplexer 202, the serial I/O multiplexer 202 will recognize that the temperature read command is not meant for it based on the address code that may be embedded in the temperature read command. And in the case of the other temperature sensors, the other temperature sensors will also not read or process the temperature read command because they will not be clocked or coupled to the clock line 212.

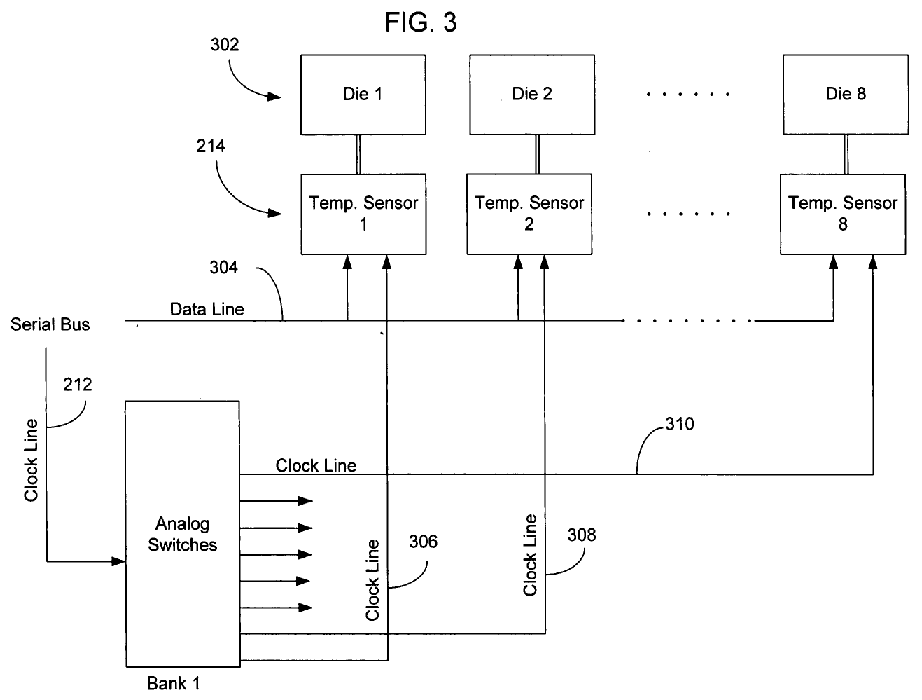

As depicted, the clock line 212 is coupled to temperature sensor 1 and will clock in the temperature read command pair to temperature sensor 1. The clock line 212 will then clock out serially the temperature measurement or measured temperature of the electronic device (i.e., die 1 in FIG. 1) that is coupled to temperature sensor 1 through the serial bus 114. As a result, temperature sensor 1 will output a measured temperature, which may be transmitted through a common I/O data line (see data line 304 of FIG. 3) and back to, for example, the control board 104 via the serial bus 114. Note again that because of the use of the clock line 212 and the data line 210 in prompting temperature sensor 1 to output a measured temperature, no data contention will occur with the other temperature sensors even though a common I/O data line 304 is used to output measured temperatures from all of the temperature sensors 214. This process may be repeated over and over again to obtain temperature readings from each of the temperature sensors 214.

FIG. 3 depicts the coupling of analog switch bank 1 of FIG. 2 and a common I/O data line to multiple temperature sensors in accordance with some embodiments. For the embodiments, the temperature sensors 214 are each coupled to different dice 302, each of the temperature sensors 214 may be assigned with unique sensor identifiers (i.e., device address code). The dice 302 may be electronic devices such as processors, volatile memory devices and chipsets that may be embedded with thermal diodes. The temperature sensors 214 are each coupled to a common data line 304, which is a common I/O line for receiving temperature read commands and for outputting temperature measurements. Each of the temperature sensors 214 are further coupled to the analog switch bank 204 via separate clock lines (e.g., clock lines 306 to 310). In this illustration, three of the clock lines 306 to 310 that are coupled to temperature sensor 1, temperature sensor 2 and temperature sensor 8 are actually shown.

As previously described, each of the temperature sensors 214 may be prompted to output temperature measurements (i.e., measured temperatures) by serially coupling each of the temperature sensor clock lines (e.g., clock lines 306 to 310) to the serial bus clock line 212 via the analog switch bank 204. As a result, no two temperature sensors 214 may output temperature measurements at the same time. Instead, the temperature sensors 214 may each be prompted to output temperature measurements in a sequential or serial manner.

FIG. 4 depicts an example temperature sensor circuitry that may be employed in accordance with some embodiments. For the embodiments, the temperature sensor circuitry 402 may include a temperature sensor 404 and assorted circuitry components. The temperature sensor 404 may be further coupled to a couple of ports or conductive leads 406 and 408. The conductive leads 406 and 408 may couple with a thermal diode that is embedded into an electronic device (e.g., die). The temperature sensor circuitry 402 may be of the type that provides both remote (e.g., die) and local (e.g., temperature sensor) temperature measurements.

The single serial bus architecture that includes a sensor selection circuitry as described above may allow for relatively accurate and precise monitoring of temperatures of multiple electronic devices on a test board. By including a sensor selection circuitry such as the one depicted in FIGS. 2 and 3 into the serial bus architecture, a fast stream of accurate temperature measurement outputs may be obtained. For example, as previously described, sampling rates of 4 Hz or higher and in some cases at least 8 Hz may be achieved. Further, an accuracy of ±1 degrees Celsius (C.°), a resolution of 0.125 C.° and a temperature range of greater than or equal to 145 C.° may be achieved using the architecture described above.

Accordingly, an apparatus for outputting multiple temperature measurements of multiple electronic devices has been described in terms of the above-illustrated embodiments. It will be appreciated by those of ordinary skill in the art that a wide variety of alternate and/or equivalent implementations calculated to achieve the same purposes may be substituted for the specific embodiments shown and described without departing from the scope of the present invention. Those of ordinary skill in the art will readily appreciate that the present invention may be implemented in a very wide variety of embodiments. This description therefore is intended to be regarded as illustrative instead of restrictive on embodiments of the present invention.

1. An apparatus, comprising:
a plurality of temperature sensors to correspondingly measure temperatures of a plurality of dice under test; and
a sensor selection circuitry coupled to the plurality of temperature sensors to selectively control each of the temperature sensors to selectively prompt each of the temperature sensors to selectively output their measured temperatures, one temperature sensor at a time.

2. The apparatus of claim 1, wherein the apparatus further comprises a data line coupled to the plurality of sensors, and the sensor selection circuitry is adapted to selectively control the temperature sensors to output their measured temperatures onto the data line, one temperature sensor at a time.

3. The apparatus of claim 1, further comprising a plurality of sockets adapted to receive the dice, one die per socket, each socket having at least one conductor to couple a die to the socket, and the temperature sensors are coupled to the sockets correspondingly.

4. The apparatus of claim 1, wherein said sensor selection circuitry is adapted to receive pairs of sensor identifiers and temperature read command.

5. The apparatus of claim 4, wherein said sensor selection circuitry is further adapted to select and prompt the plurality of temperature sensors to output their measured temperatures onto a data line, based at least in part on the received pairs of sensor identifiers and temperature read command.

6. The apparatus of claim 1, wherein said sensor selection circuitry further comprises a serial input/output (I/O) multiplexer, the serial I/O multiplexer adapted to receive at least sensor identifiers of pairs of sensor identifiers and temperature read command.

7. The apparatus of claim 6, wherein the apparatus further comprises a serial bus, the serial bus being coupled to the serial I/O multiplexer and the temperature sensors, to provide the pairs of sensor identifiers and temperature read command.

8. The apparatus of claim 7, wherein said sensor selection circuitry further comprises one or more banks of analog switches coupled to the serial I/O multiplexer, the one or more banks of analog switches coupled to the temperature sensors.

9. The apparatus of claim 8, wherein said one or more banks of analog switches are further coupled to a clock line of the serial bus.

10. The apparatus of claim 1, wherein the apparatus further comprises a substrate, and said plurality of temperature sensors are embedded in the substrate.

11. The apparatus of claim 1, wherein the apparatus further comprises a substrate, and said sensor selection circuitry is embedded in the substrate.

12. A method, comprising:
measuring temperatures of a plurality of dice under test using a plurality of temperature sensors coupled to the dice correspondingly; and
selectively controlling each of the temperature sensors with a sensor selection circuitry to selectively prompt each of the temperature sensors to selectively output their measured temperatures, one temperature sensor at a time.

13. The method of claim 12, wherein the method further comprises receiving by the sensor selection circuitry, a signal that includes pairs of sensor identifiers and temperature read command.

14. The method of claim 13, wherein said selective controlling comprises prompting the plurality of temperature sensors by the sensor selection circuitry, to generate their measured temperature, based at least in part on the sensor identifiers in the pairs of sensor identifiers and temperature read command.

15. The method of claim 12, wherein the method further comprises the temperature sensors outputting the measured temperatures onto a data line, responsive to the selective control, one temperature sensor at a time.

16. The method of claim 15, wherein said selective control comprises selectively controlling the temperature sensors to output the measured temperatures at a sampling rate of at least 4 Hz.

17. A system, comprising:
a test board, including:
a plurality of temperature sensors to correspondingly measure temperatures of a plurality of dice under test using the board;
a sensor selection circuitry coupled to the plurality of temperature sensors to selectively control each of the temperature sensors to selectively prompt each of the temperature sensors to selectively output their measured temperatures, one temperature sensor at a time; and
a control board coupled to the test board to control the sensor selection circuitry to perform the selective control.

18. The system of claim 17, wherein the test board further comprises a serial bus coupled to the plurality of temperature sensors.

19. The system of claim 17, wherein the test board further comprises a serial bus coupling the temperature sensors to the control board to facilitate the temperature sensors to provide their measured temperatures to the control board serially.

20. The system of claim 17, wherein the control board is adapted to transmit pairs of sensor identifiers and temperature read command to the sensor selection circuitry.

21. The system of claim 17, further comprising a thermal controller coupled to the control board, and adapted to control thermal conditions of the dice under test, under control of the control board.
